(19) United States
(12) Patent Application Publication
(10) Pub. No.: US 2013/0203259 A1
(43) Pub. Date: Aug. 8, 2013

(54) PRESSURE CONTROL VALVE ASSEMBLY OF PLASMA PROCESSING CHAMBER AND RAPID ALTERNATING PROCESS

(71) Applicant: Jaroslaw W Winniczek, Daly City, CA (US)

(72) Inventor: Jaroslaw W Winniczek, Daly City, CA (US)

(73) Assignee: Lam Research Corporation, Fremont, CA (US)

(21) Appl. No.: 13/367,951

(22) Filed: Feb. 7, 2012

(51) Int. Cl. H01L 21/3065; E21B 34/10; H01L 21/30

(52) U.S. Cl. 438/710; 438/758; 137/629; 257/E21.218; 257/E21.211

(57) ABSTRACT

A pressure control valve assembly of a plasma processing chamber in which semiconductor substrates are processed includes a housing having an inlet, an outlet and a conduit extending between the inlet and the outlet, the inlet adapted to be connected to an interior of the plasma processing chamber and the outlet adapted to be connected to a vacuum pump which maintains the plasma processing chamber at desired pressure set points during rapid alternating phases of processing a semiconductor substrate in the chamber. A drive mechanism attached to first and second valve plates effects rotation of the first and second valve plates to switch the valve plates between first and second angular orientations to change the degree of alignment of first and second open areas of the valve plates and thereby increase or decrease conductance to achieve desired pressure settings in the chamber.

### FIELD OF THE INVENTION

The invention relates to a pressure control valve assembly located between a vacuum pump and a plasma processing chamber in which semiconductor substrates are processed. The pressure control valve assembly can be used to effect rapid pressure changes in the plasma chamber during processing of a semiconductor substrate undergoing multi-step processing wherein changes in chamber pressure are desired.

### BACKGROUND

The Bosch process is a plasma etch process that has been widely used to fabricate deep vertical (high aspect ratio) features (with depth such as tens to hundreds of micrometers), such as trenches and vias, in the semiconductor industry. The Bosch process comprises cycles of alternating etching steps and deposition steps. Details of the Bosch process can be found in U.S. Pat. No. 5,501,893, which is hereby incorporated by reference. The Bosch process can be carried out in a plasma processing apparatus configured with a high-density plasma source, such as an inductively coupled plasma (ICP) source, in conjunction with a radio frequency (RF) biased substrate electrode. Process gases used in the Bosch process for etching silicon can be sulfur hexafluoride (SF₆) in an etching step and octofluorocyclobutane (C₄F₈) in a deposition step. The process gas used in the etching step and the process gas used in the deposition step are respectively referred to as “etch gas” and “deposition gas” hereinbelow. During an etching step, SF₆ facilitates spontaneous and isotropic etching of silicon (Si); during a deposition step, C₄F₈ facilitates the deposition of a protective polymer layer onto sidewalls as well as bottoms of the etched structures. The Bosch process cyclically alternates between etch and deposition steps enabling deep structures to be defined into a masked silicon substrate. Upon energetic and directional ion bombardment, which is present in the etching steps, any polymer film coated in the bottoms of etched structures from the previous deposition step will be removed to expose the silicon surface for further etching. The polymer film on the sidewall will remain because it is not subjected to direct ion bombardment, thereby, inhibiting lateral etching.

U.S. Patent Publication No. 2009/0242512 discloses an example of a multi-step Bosch type process in which the chamber pressure is at 35 mTorr for 5 seconds during deposition of a passivation film, 20 mTorr for 1.5 seconds during a low pressure etch step and 325 mTorr for 7.5 seconds during a high pressure etch step (see Table 4.2.1) or 35 mTorr for 5 seconds during deposition, 20 mTorr for 1.5 seconds during low pressure etch, 325 mTorr for 7.5 seconds during high pressure etch and 15 mTorr for 1 second during low pressure etch (see Table 4.2.2).

Variation in chamber pressure is desired in other processes such as atomic layer deposition, plasma enhanced CVD, multi-step processes of plasma etching openings in mask material and removal of the mask material, multi-step plasma etch processes wherein the concentration of etchant gas is periodically varied or different layers of material are sequentially etched. To reduce the overall processing time, reduction in the transition period between high and low pressure phases of such cyclical processes would be desirable. For instance, U.S. Patent Publication No. 2009/0325386 discloses a conductance limiting element for rapid adjustment of pressure in a low volume vacuum chamber on the order of tens of milliseconds. The '386 publication states that during processing, a single chemical species can be flowed in the processing region during multiple pressure cycles or different chemical species can be introduced during multiple pressure cycles with the time at high or low pressure ranging from 0.1 to 2 seconds.

### SUMMARY

According to one embodiment, a pressure control valve assembly of a plasma processing chamber in which semiconductor substrates are processed, comprises a housing having an inlet, an outlet and a conduit extending between the inlet and the outlet, the inlet adapted to be connected to an interior of the plasma processing chamber and the outlet adapted to be connected to a vacuum pump which maintains the plasma processing chamber at desired pressure set points during processing of a semiconductor substrate in the chamber, a first valve plate having a first open area therein mounted in the conduit so as to rotate about a vertical axis and allow gasses withdrawn from the chamber into the conduit to pass through the first open area, a second valve plate having a second open area therein mounted in the conduit so as to rotate about the vertical axis and adjust pressure in the chamber by varying the degree of alignment of the first and second open areas, and a drive mechanism attached to the first and second valve plates so as to rotate of the first valve plate and the second valve plate in the same direction and at speeds which vary alignment of the first and second open areas to periodically change pressure in the chamber from a higher pressure to a lower pressure and from a lower pressure to a higher pressure.

In a method of processing a semiconductor substrate in a chamber having the pressure control valve assembly attached to an outlet of the chamber, the method includes (a) adjusting chamber pressure from a lower pressure to a higher pressure by rotating the first and second valve plates in the same direction while in a first angular orientation at which the first and second open areas reduce conductance while supplying a processing gas to the chamber and (b) adjusting chamber pressure from a higher pressure to a lower pressure by rotating the first and second valve plates in the same direction while in a second angular orientation at which the first and second open areas increase conductance while supplying the same or different process gas to the chamber. The chamber is preferably an inductively coupled plasma (ICP) chamber in which RF energy is transmitted into the chamber through a dielectric window. ICP chambers used for single wafer processing of 300 mm diameter wafers can have chamber volumes of 60 to 100 liters and pressure settings in the chamber can vary from 20 mTorr to 300 mTorr. The pressure control valve assembly described herein can be fitted between a vacuum pump and the outlet of an ICP chamber having a chamber volume of over 60 liters and rapid cycling of pressure changes in the chamber can be effected by switching the valve plates between the first and second angular orientations.

In one embodiment, the processing can comprise plasma etching openings in silicon using alternating steps of etching and deposition wherein a first processing gas comprises a fluorine containing gas supplied for less than 1.3 seconds and energized into a plasma state while maintaining chamber pressure above 150 mTorr and a second processing gas comprises a fluorocarbon containing gas supplied for less than 0.7 second and energized into a plasma state while maintaining the chamber pressure below 130 mTorr. The method can further include a polymer clearing step before the etching step wherein the polymer clearing step is carried out by supplying a polymer clearing gas for at least 200 milliseconds and energizing the polymer clearing gas into a plasma state while maintaining the chamber pressure below 150 mTorr.

A further process comprises a deposition process wherein chamber pressure is repeatedly varied while supplying the same or different process gas while the chamber pressure is cycled between various set points. For example, at the different chamber pressures different process gases can be supplied or the same processing gas can be supplied at different flow rates.

### BRIEF DESCRIPTION OF THE DRAWINGS

FIG. 1 shows a plasma processing system and pressure control valve which may be used to carry out rapid alternating processing of a semiconductor substrate.

FIG. 2A shows a prior art pressure control valve system.

FIG. 2B shows a top view of a throttle valve of the system shown in FIG. 2A.

FIG. 3A shows a pressure control system incorporating a throttle valve assembly having upper and lower valve plates which are driven in rotation about a vertical axis.

FIG. 3B shows the upper and lower valve plates with open areas aligned for maximum conductance.

FIG. 3C shows the upper and lower valve plates with open areas offset for minimum conductance.

FIG. 3D shows a valve plate with gear teeth around an outer periphery thereof for engagement with a drive mechanism.

FIGS. 4A-C show embodiments of valve plates having different open area configurations wherein FIG. 4A shows a valve plate wherein the open area is a single semicircular opening, FIG. 4B shows a valve plate wherein the open area comprises two diametrically opposed openings in the form of quarter circles, and FIG. 4C shows a valve plate wherein the open area comprises four diametrically opposed openings in the form of one-eight circles.

FIGS. 5A-D show upper and lower valve plates with the configuration shown in FIG. 4C wherein FIG. 5A shows the valve plates in a fully open position, FIG. 5B shows the valve plates in a slightly closed position, FIG. 5C shows the valve plates in nearly closed position, and FIG. 5D shows the valve plates in a full closed position.

### DETAILED DESCRIPTION

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention. As used herein, the term “about” should be construed to include values up to 10% above or below the values recited.

Described herein is a pressure control valve assembly of a plasma processing chamber in which rapid pressure changes are desired. For example, deep features of semiconductor substrates can be processed by rapid alternating phases of etching and passivation (deposition of a protective layer of material) at different chamber pressures. The pressure control valve assembly is designed to minimize the time in which pressure can be changed in the plasma processing chamber. One limitation of the Bosch process is roughened sidewalls of etched deep features. This limitation is due to the periodic etch/deposition scheme used in the Bosch process and is known in the art as sidewall “scalloping”. For many device applications, it is desirable to minimize this sidewall roughness or scalloping. The extent of scalloping is typically measured as a scallop length and depth. The scallop length is the peak-to-peak distance of the sidewall roughness and is directly correlated to the etch depth achieved during a single etch cycle. The scallop depth is the peak to valley distance of sidewall roughness and is correlated to the degree of anisotropy of an individual etching step. The extent of scallop formation can be minimized by shortening the duration of each etch/deposition step (i.e. shorter etch/deposition steps repeated at a higher frequency).

In addition to smoother feature sidewalls it is also desirable to achieve a higher overall etch rate. The overall etch rate is defined as a total depth etched in a process divided by a total duration of the process. The overall etch rate can be increased by increasing efficiency within a process step (i.e. decreasing dead time).

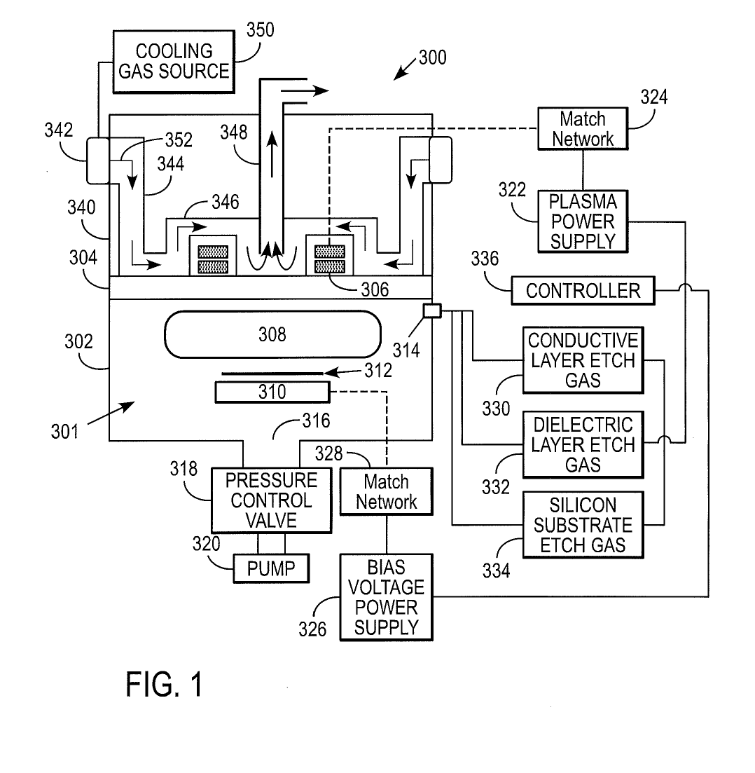

FIG. 1 shows a schematic view of a plasma processing system 300 including a plasma reactor 302 having a plasma processing chamber 301 therein. A plasma power supply 322, tuned by a match network 324 supplies power to an antenna 306 located near a window 304 to create a plasma 308 in plasma processing chamber 301. Antenna 306 may be configured to produce a uniform diffusion profile within processing chamber 301; for example, antenna 306 may be configured for a toroidal power distribution in plasma 308. Window 304 is provided between the antenna 306 and the interior of the plasma chamber 301 and is made of a dielectric material which allows RF energy to pass from antenna 306 to plasma chamber 301. A wafer bias voltage power supply 326 tuned by a match network 328 provides power to an electrode 310 to set the bias voltage on wafer 312, which is supported by electrode 310, incorporated in a substrate support which supports the wafer. Set points for plasma power supply 322 and wafer bias voltage power supply 326 are set by controller 336. The chamber 301 includes a vacuum pumping apparatus 320, and pressure control valve assembly 318, which control the interior of pressure of chamber 301.

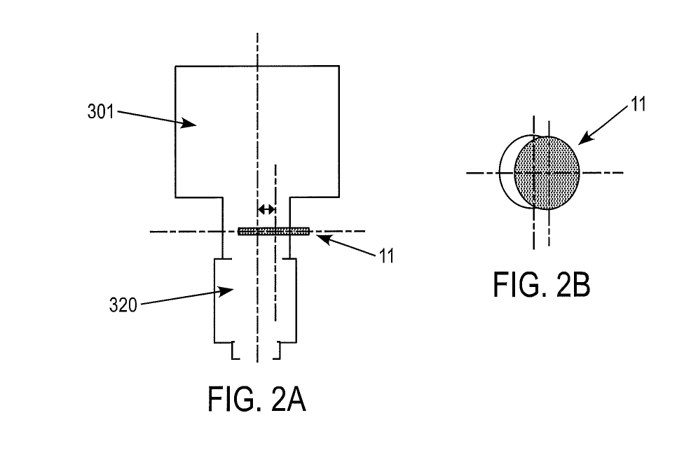

FIG. 2A illustrates a conventional pressure control valve assembly. The pressure control valve assembly includes a pendulum throttle valve 11 between the process chamber 301 and turbomolecular pump 320 of the plasma processing system 300. Pivotal movement of the throttle valve 11 is controlled by a stepper motor, (not shown) which at count 0 the valve is fully closed and at count 1000 is fully opened. As shown in FIG. 2B, the throttle valve 11 is swung across the conduit between the chamber 301 and the vacuum pump 320 to control gas flow conductance.

Many rapid alternating processes for high aspect ratio features in silicon require considerable changes of pressure between passivating and etching phases. Most rapid alternating processes require throttle valve movement between 50 and 250 counts in less than 300 milliseconds, and current vacuum systems are not capable of covering this required range. As an example, it may be desirable to move a throttle valve from a maximum of 255 counts to a minimum position of 90 counts in under 300 milliseconds. However, with a pendulum throttle valve it may only be possible to move the valve from a maximum of 235 counts to a minimum position of 90 counts in 340 milliseconds (425 counts/second). The pendulum valve requires reversal of angular momentum for a pressure change to occur from high to low pressure or from low to high pressure and in RAP processes the pendulum valve must reverse direction before it reaches a desired position since the valve must stop before it can reverse direction. Disclosed herein is a throttle valve system wherein momentum of the valve is not reversed.

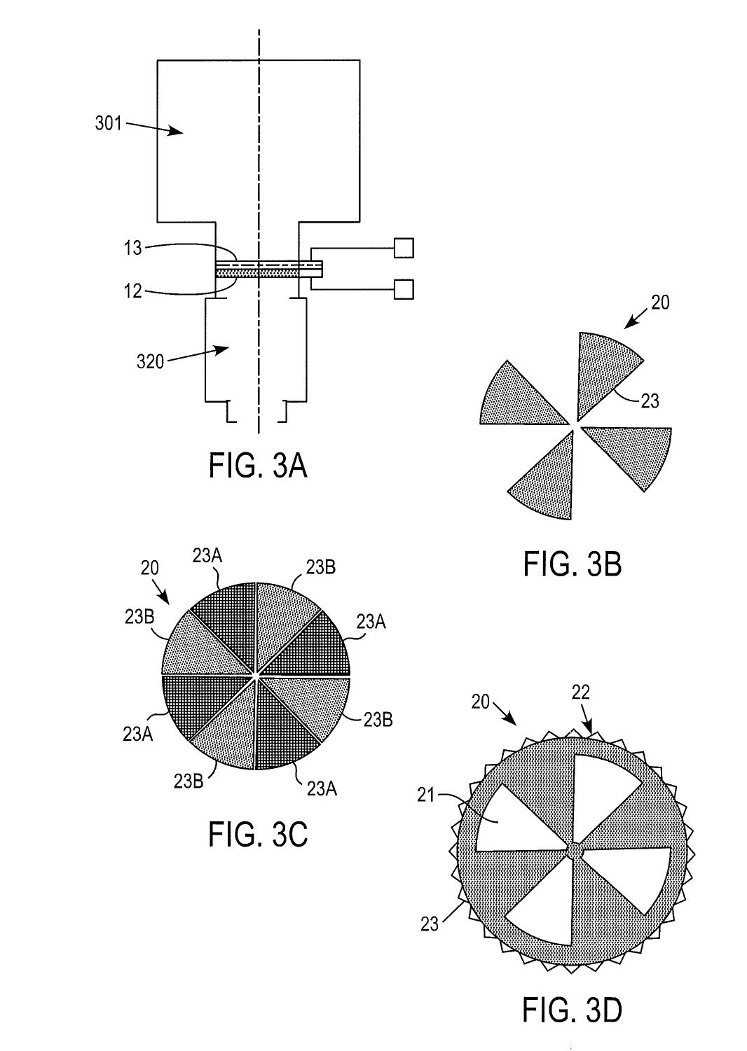

FIG. 3A shows an embodiment of a pressure control system wherein a pressure control valve assembly 2 includes a housing 3 having an inlet 4, an outlet 5 and a conduit 6 extending between the inlet and the outlet, the inlet adapted to be connected to an interior of the plasma processing chamber 301 and the outlet adapted to be connected to a vacuum pump 320 which maintains the plasma processing chamber at desired pressure set points during processing of a semiconductor substrate in the chamber. The pressure control valve assembly includes a first valve plate 12 having a first open area therein and mounted in the conduit such that the first valve plate is rotatable about a vertical axis. Gasses withdrawn from the chamber into the conduit pass through the first open area. A second valve plate 13 having a second open area therein is mounted in the conduit such that the second valve plate is rotatable about the vertical axis.

FIG. 3D shows an example of a valve plate 20 having an open area in the form of four triangular slots 21 in the form of one-eight segments of a circle formed by four vanes 23 and gear teeth 22 around the periphery of the valve plate to allow side driven rotation of the valve plate 20. FIG. 3B shows upper and lower valve plates with the open area configuration shown in FIG. 3D in a fully open position and FIG. 3C shows the valve plates wherein vanes 23A of the upper valve plate block the open area of the lower valve plate and vanes 23B of the lower valve plate block the open area of the upper valve plate.

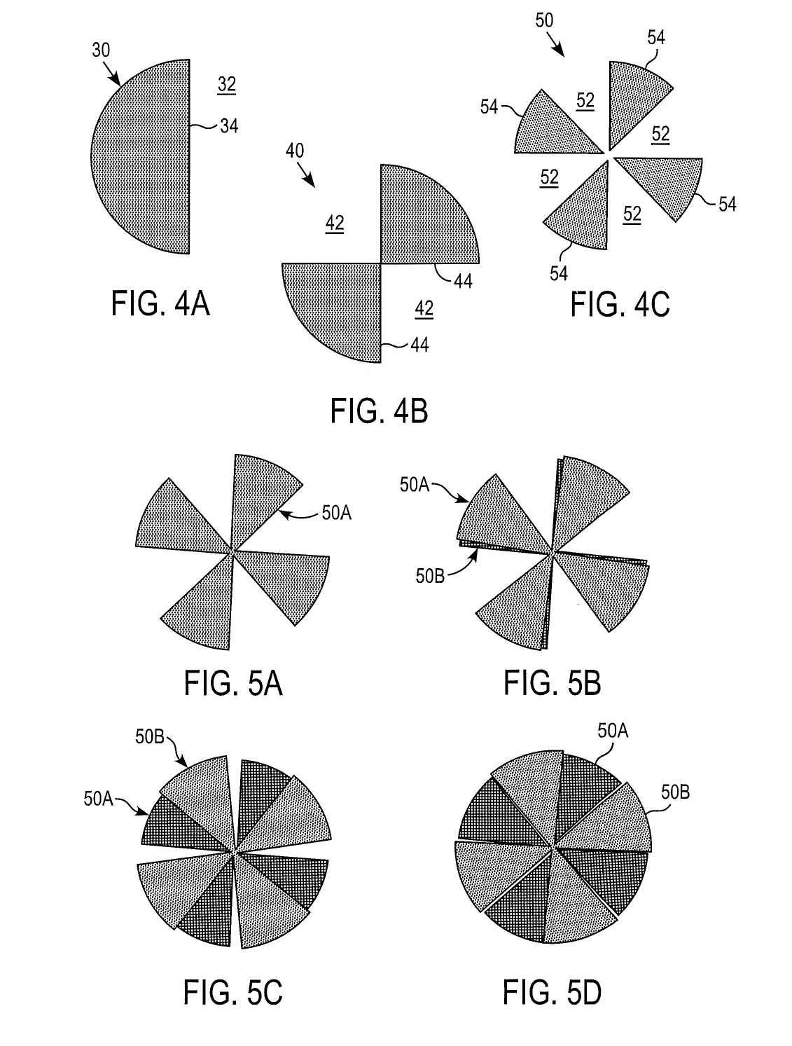

FIGS. 4A-C show valve plates with different open area configurations. FIG. 4A shows a valve plate 30 wherein the open area 32 is a single semicircular opening and the vane 34 is a D-shaped solid plate. FIG. 4B shows a valve plate 40 wherein the open area comprises two diametrically opposed openings 42 in the form of quarter circles formed by vanes 44 having the same size and shape as the openings 42. FIG. 4C shows a valve plate 50 wherein the open area comprises four diametrically opposed openings 52 in the form of one-eight circles formed by four vanes 54 having the same size and shape as the openings 52.

FIGS. 5A-D show upper and lower valve plates 50A, 50B with the configuration shown in FIG. 4C. FIG. 5A shows the valve plates 50A, 50B in a fully open position, FIG. 5B shows the valve plates 50A, 50B in a slightly closed position, FIG. 5C shows the valve plates 50A, 50B in nearly closed position, and FIG. 5D shows the valve plates 50A, 50B in a full closed position.

In contrast to pendulum valves which change direction during pressure changes, the first and second valve plates are independently driven in rotation so as to rotate in the same direction. The rotation speed of the first and/or second valve plate can be varied to change the degree of alignment of the open areas of the rotating valve plates. For example, the angular orientation of the upper and lower valve plates can be changed such that the lower valve plate blocks the first open area to a greater extent in the first position than in the second position. During pressure changes in the chamber, one valve plate can be driven at a constant speed while the other valve plate has a variable speed to change the degree of overlap of open areas in the upper and lower valve plates and thereby vary conductance.

The upper and lower valve plates can be driven with various drive arrangements to achieve alternating higher and lower conductance positions of the valve plates. For example, while one valve plate rotates at a constant speed, the other valve plate can be given a momentary increase in speed to change the relative positions of the open areas in the upper and lower valve plates and then the both valve plates can be driven at the same speed until the next change in relative positions of the open areas, In another drive scheme, both valve plates can be driven at variable speeds to periodically change the relative positions of the open areas. The speed of rotation can be slower in the case of a larger number of openings forming the open areas since less of a change in angular orientation is needed to achieve maximum and minimum conductance. Thus, by rotating the valve plates between reduced conductance and increased conductance it is possible to rapidly change the chamber pressure between higher and lower pressure settings.

In use, a semiconductor substrate can be processed in a chamber having the pressure control valve assembly attached to an outlet of the chamber. The processing can include adjusting chamber pressure to a higher pressure by rotating the upper and lower valve plates in a first angular orientation such that the open areas in the valve plates are more blocked while supplying a processing gas to the chamber. The chamber pressure can be adjusted to a lower pressure by rotating the upper and lower valve plates in a second angular orientation such that the open areas in the valve plates are less blocked to increase flow conductance of gases removed from the chamber. The chamber can be an inductively coupled plasma chamber having a chamber volume of over 60 liters.

The open area of the valve plates can be 25 to 50%, preferably about 50%. The speed of changing the flow conductance can be increased by using valve plates with a larger number of openings. For example, the valve plates can each have 2 to 20 openings of equal size and shape. The space between the openings is preferably a mirror image of the openings.

The upper and lower valve plates preferably have identical open areas so that alignment of the open areas corresponds to maximum conductance and blockage of the open areas corresponds to minimum conductance. The upper and lower valve plates are preferably side driven by separate stepper motors which drive the valve plates at speeds dictated by a controller. In a preferred method, the valve plates can be switched from their first angular orientation to their second angular orientation and from their second angular orientation to their first angular orientation within 100 milliseconds (ms), e.g., within 70 ms.

The plasma processing apparatus can be used to etch silicon on a semiconductor substrate supported on a substrate support at a rate of at least 10 μm/min and the plasma processing apparatus can alternately supply etch gas and deposition gas in a plasma confinement zone (chamber gap) in the processing chamber within about 500 milliseconds. In one embodiment, the etching gas is a fluorine containing gas such as SF₆ and the deposition gas is a fluorocarbon containing gas such as C₄F₈.

In operation, the gas supply system preferably does not divert the etching gas to a vacuum line during supply of the deposition gas to the chamber and does not divert the deposition gas to a vacuum line during supply of the etching gas to the chamber. Processing of a substrate using the plasma processing apparatus described above preferably comprises (a) supporting the substrate in the chamber, (b) supplying the etching gas to the chamber, (c) energizing the etching gas in the chamber into a first plasma and processing the substrate with the first plasma, (d) supplying the deposition gas to the chamber, (e) energizing the deposition gas in the chamber into a second plasma and processing the substrate with the second plasma, (f) repeating steps (b)-(e) with a total cycle time of no greater than 1.8 seconds. The etching gas preferably replaces at least 90% of the deposition gas within a period of about 500 milliseconds in step (b), and the deposition gas preferably replaces at least 90% of the etching gas within a period of about 500 milliseconds (d). During the process, pressure in the chamber is varied from a first pressure setting to a second pressure setting during steps (b)-(e) while switching the rotating upper and lower valve plates between different angular orientations. During a cycle of supplying the etching gas and deposition gas, a total time of supplying the etching gas can be 1.5 seconds or less and a total time of supplying the deposition gas can be 1 second or less. For example, using SF₆ as the etch gas and C₄F₈ as the deposition gas, pressure can be maintained above 150 mTorr in step (c) and below 140 mTorr in step (e).

Chamber pressure can be rapidly adjusted by rotating the upper and lower valve plates in a first angular orientation at which their open areas are more blocked to maintain higher chamber pressure during step (c) and rotating the upper and lower valve plates in a second angular orientation at which their open areas are less blocked to maintain lower chamber pressure during step (e). Thus, it is possible to maintain pressure in the chamber during supply of the etching gas greater than 70 mTorr (e.g., 80 mTorr) or greater than 150 mTorr (e.g., 180 mTorr) and pressure in the chamber during supply of the deposition gas less than 140 mTorr (e.g., 120 mTorr) or less than 60 mTorr (e.g., 50 mTorr). In a preferred process, the etching gas is supplied to the chamber at a flow rate of at least 500 sccm and the deposition gas is supplied to the chamber at a flow rate of less than 500 sccm. The alternate steps of supplying etching gas and deposition gas can be carried out for at least 100 cycles.

During the supply of the etching gas the substrate can be subjected to plasma etching of high aspect ratio openings with pressure in the chamber maintained at less than 150 mTorr for 200 milliseconds during a polymer clearing phase of the etching step and at over 150 mTorr for the remainder of the plasma etching step. During the supply of the deposition gas the second plasma can deposit a polymer coating on sidewalls of the openings with pressure in the chamber maintained at less than 150 mTorr for the entire deposition step. The etching gas can be one or more of SF₆, CF₄, XeF₂, NF₃, Cl containing gas such as CCl₄ and the deposition gas can be a fluorocarbon containing gas such as one or more of C₄F₈, C₄F₆, CH₂F₂, C₃F₆, CH₃F. The etching gas can be supplied through any suitable gas delivery system including fast acting valves wherein fast acting solenoid valves upon receiving a signal from a controller send pneumatic air to fast switching valves within 10 milliseconds and total time to open or close the fast switching valves can be 30 milliseconds or less.

The pressure control valve assembly can also be used in processing other than etching. For example, the pressure control valve assembly can be incorporated in a deposition chamber in which films are deposited on semiconductor substrates. For deposition processes wherein it is desired to cycle chamber pressure while varying the gas flows in the chamber, the upper and lower valves can be reciprocated between higher conductance and lower conductance angular orientations to effect pressure changes in the chamber.

Having disclosed the exemplary embodiments and the best mode, modifications and variations may be made to the disclosed embodiments while remaining within the subject and spirit of the invention as defined by the following claims.

What is claimed is:

1. A pressure control valve assembly of a plasma processing chamber in which semiconductor substrates are processed, comprising:
a housing having an inlet, an outlet and a conduit extending between the inlet and the outlet, the inlet adapted to be connected to an interior of the plasma processing chamber and the outlet adapted to be connected to a vacuum pump which maintains the plasma processing chamber at desired pressure set points during processing of a semiconductor substrate in the chamber;
a first valve plate having a first open area therein mounted in the conduit so as to rotate about a vertical axis and allow gasses withdrawn from the chamber into the conduit to pass through the first open area;
a second valve plate having a second open area therein mounted in the conduit so as to rotate about the vertical axis and adjust pressure in the chamber by varying the degree of alignment of the first and second open areas;
a drive mechanism attached to the first and second valve plates so as to rotate the first valve plate and the second valve plate in the same direction and at speeds which vary alignment of the first and second open areas to periodically change pressure in the chamber from a higher pressure to a lower pressure and from a lower pressure to a higher pressure.

2. The pressure control valve assembly of claim 1, wherein the first valve plate is an upper valve plate driven at a constant or variable speed of rotation and the second valve plate is a lower valve plate driven at a constant or variable speed.

3. The pressure control valve assembly of claim 2, wherein the drive mechanism includes:
a first motor and gear mechanism operable to rotate the upper valve plate by engaging an outer periphery of the upper valve plate;
a second motor and gear mechanism operable to rotate the lower valve plate by engaging an outer periphery of the lower valve plate; and
a controller operable to change angular orientations of the upper and lower valve plates between a first angular orientation at which the upper and lower valve plates provide a higher flow conductance through the conduit and a second angular orientation at which the upper and lower valve plates provide a lower flow conductance through the conduit, the controller further operable to drive the first and second motors such that the upper and lower valve plates rotate at the same speed when in the first angular orientation, at the same speed when in the second angular orientation and at different speeds when the upper and lower valve plates are switched between their first and second angular orientations.

4. The pressure control valve assembly of claim 3, wherein the first and second motors are stepper motors and the controller is operable to switch the upper and lower valve plates from the first angular orientation to the second angular orientation within 100 milliseconds.

5. The pressure control valve assembly of claim 2, wherein the upper and lower valve plates are circular, the first open area is about 50% of the cross section of the upper valve plate and the second open area is about 50% of the cross section of the lower valve plate.

6. The pressure control valve assembly of claim 2, wherein the upper and lower valve plates include triangular vanes and the first and second open areas are located between the triangular vanes.

7. The pressure control valve assembly of claim 6, wherein the upper and lower valve plates are identical in shape and have at least two to four triangular vanes.

8. The pressure control valve assembly of claim 2, wherein the upper and lower valve plates are identical in shape and the first and second open areas are semicircular in shape.

9. The pressure control valve assembly of claim 3, wherein the upper and lower valve plates include gear teeth around an outer periphery thereof, the gear teeth engaging gears coupled to the first and second motors.

10. The pressure control valve assembly of claim 4, wherein the stepper motors are 500 count per second or faster stepper motors operable to switch the upper and lower valve plates from the first angular orientation to the second angular orientation within 70 milliseconds.

11. A method of processing a semiconductor substrate in a chamber having the pressure control valve assembly of claim 1 attached to an outlet of the chamber, comprising steps: (a) adjusting chamber pressure from a lower pressure to a higher pressure by rotating the first and second valve plates in the same direction while in a first angular orientation at which the first and second open areas reduce conductance while supplying a processing gas to the chamber and (b) adjusting chamber pressure from a higher pressure to a lower pressure by rotating the first and second valve plates in the same direction while in a second angular orientation at which the first and second open areas increase conductance while supplying the same or different process gas to the chamber.

12. The method of claim 11, wherein the processing comprises plasma etching openings in silicon using alternating steps of etching while supplying an etching gas to the chamber and deposition while supplying a deposition gas to the chamber, the etching gas comprising a fluorine containing gas supplied for less than 1.3 seconds and energized into a plasma state while maintaining the first pressure above 150 mTorr and the deposition gas comprising a fluorocarbon containing gas supplied for less than 0.7 second and energized into a plasma state while maintaining the second pressure below 130 mTorr.

13. The method of claim 12, further comprising a polymer clearing step before the etching step, the polymer clearing step being carried out by supplying a polymer clearing gas for at least 200 milliseconds and energizing the polymer clearing gas into a plasma state while maintaining the chamber pressure below 150 mTorr.

14. The method of claim 11, wherein the processing comprises depositing a film on the substrate.

15. The method of claim 11, wherein rapid alternating of steps (a) and (b) is carried out for at least 100 cycles.

16. The method of claim 11, wherein the valve plates are switched from their first angular orientation to their second angular orientation within 300 milliseconds.

17. The method of claim 11, wherein the chamber is an inductively coupled plasma chamber having a chamber volume of at least 60 liters and the processing comprises energizing etching gas into a plasma state and plasma etching the semiconductor substrate.

18. The method of claim 11, wherein the processing comprises a deposition process wherein chamber pressure is repeatedly varied while supplying the same or different process gas while the chamber is cycled between various set points.
